(19) United States
(12) Patent Application Publication
(10) Pub. No.: US 2023/0178486 A1
(43) Pub. Date: Jun. 8, 2023

(54) BACKSIDE METALLIZATION FOR SEMICONDUCTOR ASSEMBLY

(71) Applicant: Qorvo US, Inc., Greensboro, NC (US)

(72) Inventors: Tarak A. Railkar, Plano, TX (US); Kevin J. Anderson, Plano, TX (US); Tejpal Kaur Hooghan, Parker, TX (US); Deep C. Dumka, Richardson, TX (US)

(21) Appl. No.: 17/657,428

(22) Filed: Mar. 31, 2022

Related U.S. Application Data
(60) Provisional application No. 63/285,247, filed on Dec. 2, 2021.

(51) Int. Cl. H01L 23/528; H01L 23/367

(52) U.S. Cl. CPC H01L 23/5283; H01L 23/367

(57) ABSTRACT

Backside metallization techniques for a semiconductor assembly are disclosed. In one aspect, a die, such as a radio frequency (RF) die, within a semiconductor package may include backside metallization for RF performance reasons. The metallization is generally planar and covers a surface of the RF die. Exemplary aspects of the present disclosure cause the metallization to include trenches or grooves to allow for better expansion and contraction during thermal cycling of the RF die. In particular, the trenches decrease a modulus of the metallization layer and act as a shock absorber and allow for compression and expansion of the metallization to match the compression and expansion of the non-metal substrate of the RF die. By allowing for better matching of the compression and expansion of the two heterogeneous materials, delamination may be delayed or averted.

### PRIORITY CLAIM

The present application claims priority to U.S. Provisional Patent Application Ser. No. 63/285,247 filed on Dec. 2, 2021 and entitled “PATTERNED METALLIZED BACKSIDE OF WIRE-BONDABLE DIE,” the contents of which is incorporated herein by reference in its entirety.

### BACKGROUND

I. Field of the Disclosure

The technology of the disclosure relates generally to semiconductor packages that include backside metallization of a semiconductor assembly for performance reasons and, particularly, for a die with backside metallization that can handle multiple thermal cycles without delamination.

### II. Background

Computing devices abound in modern society, and more particularly, mobile communication devices have become increasingly common. The prevalence of these mobile communication devices is driven in part by the many functions that are now enabled on such devices. Increased processing capabilities in such devices mean that mobile communication devices have evolved from pure communication tools into sophisticated mobile entertainment centers, thus enabling enhanced user experiences. The increased functionality has caused evolutions within wireless standards that support the increased flow of data to the mobile communication devices. The newer wireless standards in turn have caused changes in power amplifiers associated with transmission chains that comply with the newer wireless standards. In many instances, the power amplifiers are becoming larger in physical size which leads to various mechanical challenges. These mechanical challenges in turn provide room for innovation.

### SUMMARY

Aspects disclosed in the detailed description include backside metallization techniques for a semiconductor assembly. A die, such as a radio frequency (RF) die, within a semiconductor assembly may include a backside metallization layer for RF performance reasons. The metallization layer is generally planar and covers a surface of the RF die. Exemplary aspects of the present disclosure cause the metallization layer to include trenches or grooves to allow for better expansion and contraction during thermal cycling of the RF die. In particular, the trenches decrease a modulus of the metallization layer and act as a shock absorber and allow for compression and expansion of the metallization layer to match the compression and expansion of the non-metal substrate of the RF die. By allowing for better matching of the compression and expansion of the two heterogeneous materials, die delamination may be delayed or averted.

In this regard in one aspect, a semiconductor assembly is disclosed. The semiconductor assembly comprises a die comprising a backside. The semiconductor assembly also comprises a metallization layer patterned on the backside. The metallization layer comprises at least one trench within a boundary of the metallization layer.

### BRIEF DESCRIPTION OF THE DRAWINGS

FIG. 1A is an underside plan view of a trenched backside metallization layer on a die according to an exemplary aspect of the present disclosure;

FIG. 1B is a side elevation view of the die of FIG. 1A showing the trenches in a cross-sectional view;

FIG. 2A is an underside plan view of a partially trenched backside metallization layer on a die according to an exemplary aspect of the present disclosure;

FIG. 2B is a side elevation view of the die of FIG. 2A showing the partial trenches in a cross-sectional view;

FIG. 3A is an underside plan view of a non-uniformly trenched backside metallization layer on a die according to an exemplary aspect of the present disclosure;

FIG. 3B is a side elevation view of the die of FIG. 3A showing the non-uniform trenches in a cross-sectional view;

FIG. 4A is an underside plan view of a non-uniformly, partially trenched backside metallization layer on a die according to an exemplary aspect of the present disclosure;

FIG. 4B is a side elevation view of the die of FIG. 4A showing the partial trenches in a cross-sectional view;

FIG. 5 is an underside plan view of a rounded-corner-trenched backside metallization layer on a die according to an exemplary aspect of the present disclosure;

FIG. 6 is an underside plan view of an oval-shaped, trenched backside metallization layer on a die according to an exemplary aspect of the present disclosure;

FIG. 7 is an underside plan view of a trenched backside metallization layer on a die according to an exemplary aspect of the present disclosure;

FIG. 8 is an underside plan view of a rounded-corner-trenched backside metallization layer on a die according to an exemplary aspect of the present disclosure;

FIG. 9 is an underside plan view of an x-trenched backside metallization layer on a die according to an exemplary aspect of the present disclosure;

FIG. 10 is an underside plan view of a circularly-trenched backside metallization layer on a die according to an exemplary aspect of the present disclosure;

FIG. 11 is an underside plan view of a typical untrenched backside metallization layer; and

FIG. 12 is a graph of normalized strain for the various configurations of FIGS. 7-11 with two different thicknesses of the backside metallization layer.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include backside metallization techniques for a semiconductor assembly. A die, such as a radio frequency (RF) die, within a semiconductor assembly may include backside metallization layer for RF performance reasons. The metallization layer is generally planar and covers a surface of the RF die. Exemplary aspects of the present disclosure cause the metallization layer to include trenches or grooves to allow for better expansion and contraction during thermal cycling of the RF die. In particular, the trenches decrease a modulus of the metallization layer and act as a shock absorber and allow for compression and expansion of the metallization layer to match the compression and expansion of the non-metal substrate of the RF die. By allowing for better matching of the compression and expansion of the two heterogeneous materials, delamination may be delayed or averted.

Before addressing exemplary aspects of the present disclosure, it should be appreciated that an RF die may include a backside metallization layer for a variety of reasons including providing a good ground plane for electrical elements within the die and providing a suitable surface for die-attach. Further, the metallization layer may provide hot spot mitigation or other thermal management. This metallization layer may be approximately four micrometers (4 μm), although other dimensions (e.g., as thin as 0.1 ƒm) may also be appropriate depending on use. The metallization layer may, in some cases, be used on a relatively large die (e.g., greater than two millimeters by two millimeters (2 mm×2 mm)). Such a die may be a gallium nitride (GaN) or gallium arsenide (GaAs) die having a silicon carbide (SiC), aluminum nitride (AlN), silicon (Si) or diamond substrate on which the metallization layer is formed or patterned. The metallization layer may include materials such as gold (Au), copper (Cu), silver (Ag), nickel (Ni), platinum (Pt), titanium (Ti), chromium (Cr), Tungsten (W), or a combination of these different materials and may be attached to a lead frame, chip carrier, laminate, or other suitable substrate to form a semiconductor assembly. The attachment to the lead frame may be performed through a metallic die-attach material such as a gold-tin or other suitable material. The heterogeneous collection of materials in the semiconductor packaging process may result in a high mismatch between respective coefficients of thermal expansion (CTE). Such CTE mismatch means that during thermal cycling the materials may expand and contract at different rates and/or by different amounts. Collectively, this high degree of CTE mismatch may result in delamination between the die and the die attach material or between the die attach and the lead frame. Such delamination may result in reduced performance, reduced lifetime, and/or device failure.

Exemplary aspects of the present disclosure introduce a mechanical mechanism that decreases the effective modulus of the metallization layer such that expansion and contraction forces are mitigated, lowering or eliminating the risk of delamination across many thermal cycles. In a particular aspect, this mechanical mechanism is one or more trenches formed within the metallization layer.

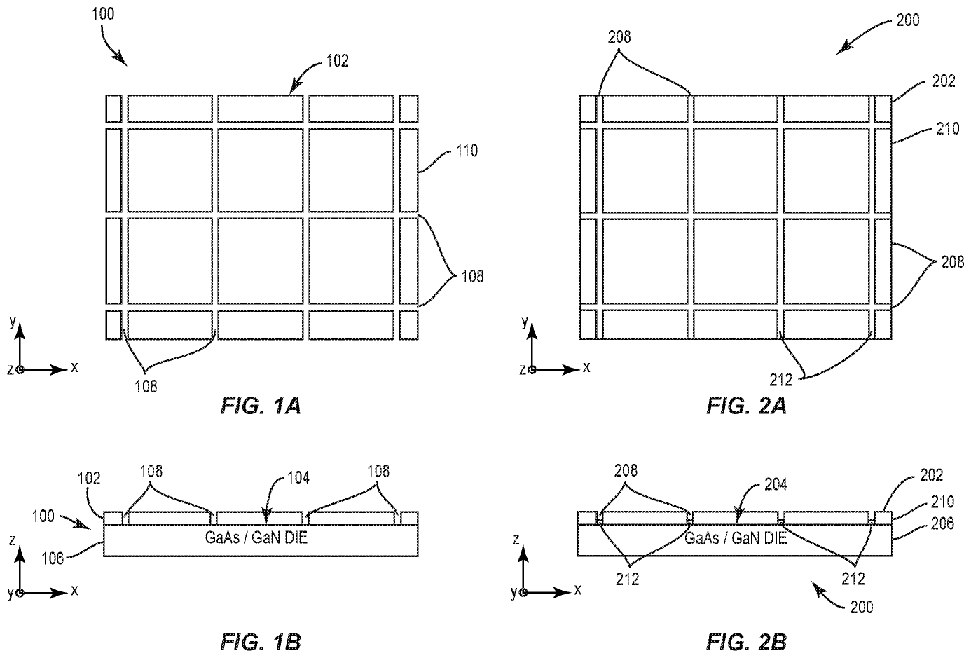

In this regard, FIGS. 1A and 1B show top and side views of a die 100 having a metallization layer 102 on an “underside” or “backside” 104 of the die 100. The backside 104 is a planar surface of a substrate 106. As used herein, backside is meant to be the side of the die 100 opposite a side that has active elements such as transistors and the like. Trenches 108 are provided within the boundary 110 of the metallization layer 102. In the die 100, the trenches 108 are uniformly spaced across the x-y axes, forming uniformly-sized portions of the metallization layer 102. Likewise, the trenches 108 extend through the entire z-axis dimension of the metallization layer 102 exposing the substrate 106.

In contrast, FIGS. 2A and 2B show top and side views of a die 200 having a metallization layer 202 on an “underside” or “backside” 204 of the die 200. The backside 204 is a planar surface of a substrate 206. Trenches 208 are provided within the boundary 210 of the metallization layer 202. In die 200, the trenches 208 are uniformly spaced across the x-y axes, forming uniformly-sized portions of the metallization layer 202. However, unlike the trenches 108, the trenches 208 extend only through a portion of the metallization layer 202 along the z-axis, leaving a fill 212.

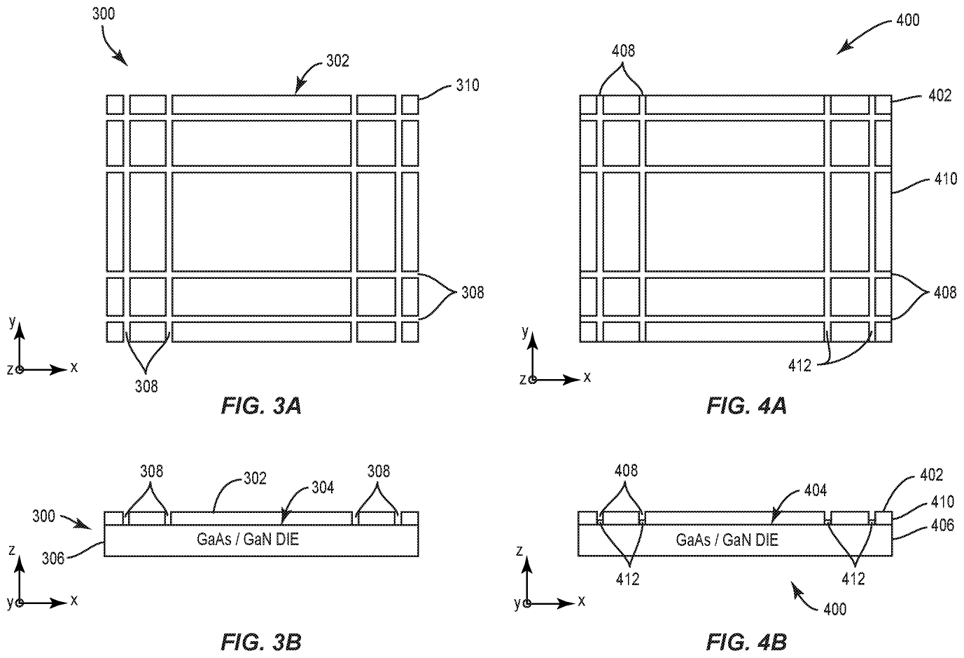

While uniformly-spaced trenches 108, 208 are possible, such trenches are not required. In contrast, FIGS. 3A and 3B show top and side views of a die 300 having a metallization layer 302 on an “underside” or “backside” 304 of the die 300. The backside 304 is a planar surface of a substrate 306. Trenches 308 are provided within the boundary 310 of the metallization layer 302. In the die 300, the trenches 308 are non-uniformly spaced across the x-y axes, forming non-uniformly-sized portions of the metallization layer 302. However, the trenches 308 extend through the entire z-axis of the metallization layer 302 along the z-axis, exposing the substrate 306.

FIGS. 4A and 4B show top and side views of a die 400 having a metallization layer 402 on an “underside” or “backside” 404 of the die 400. The backside 404 is a planar surface of a substrate 406. Trenches 408 are provided within the boundary 410 of the metallization layer 402. In the die 400, the trenches 408 are non-uniformly spaced across the x-y axes, forming non-uniformly-sized portions of the metallization layer 402. However, unlike the trenches 308, the trenches 408 extend only through a portion of the metallization layer 402 along the z-axis, leaving a fill 412.

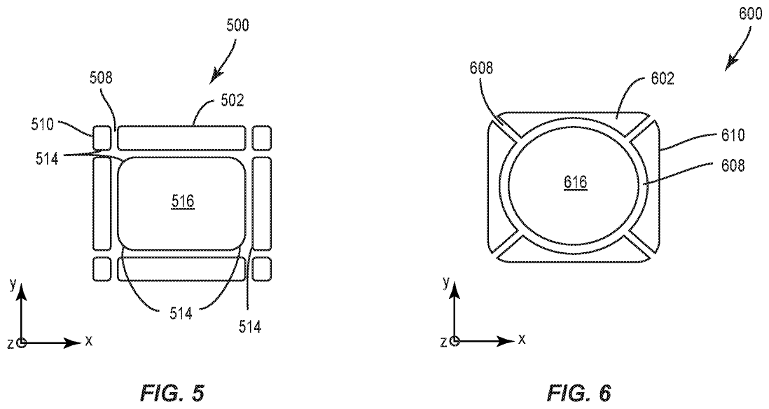

While the trenches 108, 208, 308, and 408 are rectilinear, the present disclosure is not so limited. In this regard, FIG. 5 shows a top view of a die 500 having a metallization layer 502 on a backside of the die 500. Trenches 508 are provided within the boundary 510 of the metallization layer 502. In the die 500, the trenches 508 may have rounded corners 514. The radius of curvature of the rounded corners 514 may be uniform or varied as needed or desired. The trenches 508 may delimit a large central area 516, which is generally rectilinear (albeit with the rounded corners). Rounded corners may also be used with any of the previous aspects. The trenches 508 may extend only through a portion of the metallization layer 502 along the z-axis, leaving a fill, or the trenches 508 may extend completely through the metallization layer 502 in the z-axis.

FIG. 6 shows a top view of a die 600 having a metallization layer 602 on a backside of the die 600. Trenches 608 are provided within the boundary 610 of the metallization layer 602. The trenches 608 may delimit a large central area 616, which is generally oval although trenches formed from other forms of arcuate segments may be used. Note also, that the trenches 608 may include both arcuate segments and linear segments. The trenches 608 may have uniform width or have varied width. The trenches 608 may extend only through a portion of the metallization layer 602 along the z-axis, leaving a fill, or the trenches 608 may extend completely through the metallization layer 602 in the z-axis.

By providing trenches in whatever configuration within the backside metallization layer, the effective modulus of the backside metallization layer is decreased. That is, the air gaps within the trenches give room for the backside metallization layer to flex and bend as thermal cycling causes the material of the layer to expand and contract. This air gap serves as an effective shock absorber when the metallization layer expands and contracts at different rates than other materials in the semiconductor assembly so that less strain is put on the bond, resulting in less likelihood of delamination.

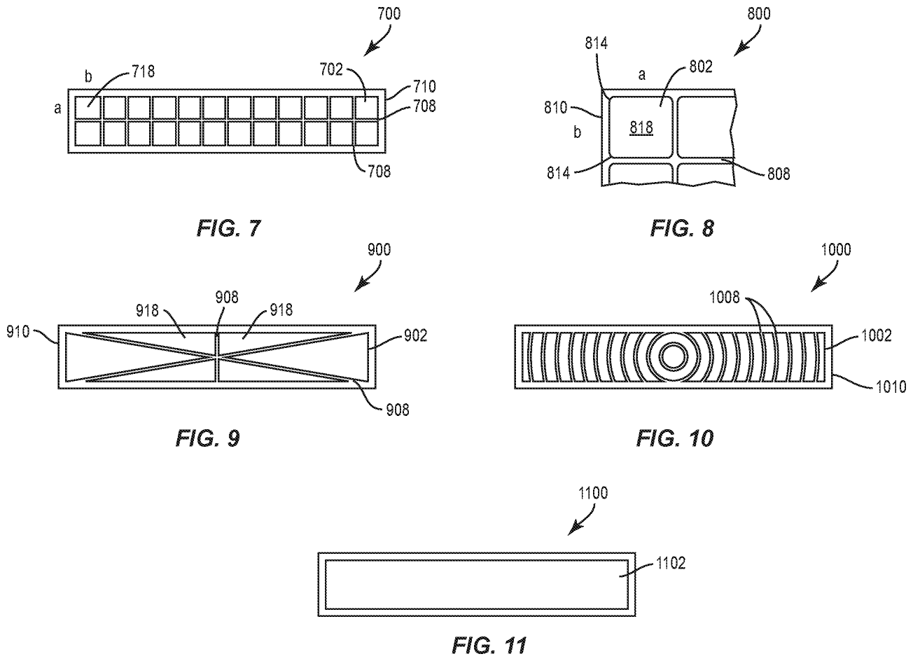

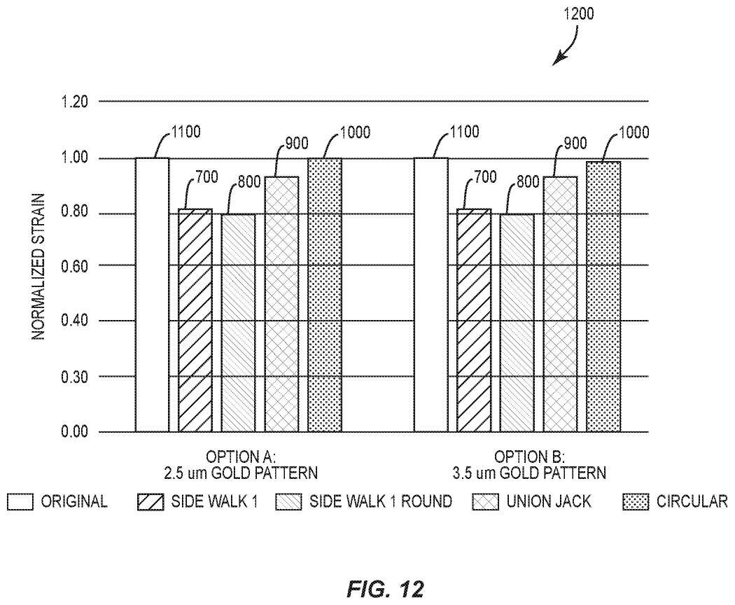

FIGS. 7-11 illustrate various configurations of trenches followed by a graph 1200 in FIG. 12 showing comparative results about the efficaciousness of the configurations in reducing strain. In this regard, FIG. 7 shows a top view of a die 700 having a metallization layer 702 on a backside of the die 700. Trenches 708 are provided within the boundary 710 of the metallization layer 702. The die 700 is substantially similar to the die 100 of FIGS. 1A and 1B with rectilinear trenches 708 and uniformly-spaced trenches 708. That is, a given portion 718 may be square, having sides a=sides b. For the purposes of the graph 1200 in FIG. 12, the trenches 708 extend all the way through the metallization layer 702 and a=b=50 μm.

FIG. 8 shows a top view of a die 800 having a metallization layer 802 on a backside of the die 800. Trenches 808 are provided within the boundary 810 of the metallization layer 802. The die 800 has rectilinear trenches 808 and uniformly-spaced trenches 808, but with rounded corners 814. A given portion 818 may be square, having sides a=sides b. For the purposes of the graph 1200 in FIG. 12, the trenches 808 extend all the way through the metallization layer 802, a=b=50 μm, and a radius of curvature of the rounded corners 814 is 20 μm.

FIG. 9 shows a top view of a die 900 having a metallization layer 902 on a backside of the die 900. Trenches 908 are provided within the boundary 910 of the metallization layer 902. The trenches 908 are not rectilinear in nature and form an x or cross (or both) creating triangular portions 918. For the purposes of the graph 1200 in FIG. 12, the trenches 908 extend all the way through the metallization layer 902.

FIG. 10 shows a top view of a die 1000 having a metallization layer 1002 on a backside of the die 1000. Trenches 1008 are provided within the boundary 1010 of the metallization layer 1002. The die 1000 has circular trenches 1008 centered on a common center in a central portion of the metallization layer 1002. For the purposes of the graph 1200 in FIG. 12, the trenches 1008 extend all the way through the metallization layer 1002 and the pitch of the trenches 1008 is uniform.

FIG. 11 provides a die 1100 with a conventional metallization layer 1102 without trenches.

FIG. 12 illustrates the graph 1200 having normalized strain illustrated for two thicknesses of metallization layers corresponding to the dies 700, 800, 900, 1000, 1100. Specifically thicknesses of 2.5 μm and 3.5 μm were tested. As can be seen, the dies 700, 800 have an almost twenty percent reduction in strain. Such reduction should help reduce or eliminate the delamination observed in conventional dies.

The metallization layers disclosed herein such as the metallization layers 102, 202, 302, 402, 502, 602, 702, 802, 902, and 1002 may be gold (Au) or copper (Cu) or other metal as needed or desired. The metallization layers may be formed by electron beam evaporation, electroplating, chemical vapor deposition (CVD), sputtering, physical vapor deposition (PVD), or the like.

The trenches 108, 208, 308, 408, 508, 608, 708, 808, 908, and 1008 may be formed by mechanically scoring the metallization layer or wet or dry etching of the metallization layer after patterning the die or wafer backside using a suitable mask, such that when the mask is removed, the trenches remain or other technique as needed or desired. Still other techniques may be used without departing from the present disclosure. While it is contemplated that the trenches within a die may have uniform width and uniform depth, such is not required. Thus, some trenches could be partial, leaving a fill and other trenches within a single die may be complete, exposing the substrate.

While some specific dimensions for the pitch, width, and depth of the trenches is provided, it should be appreciated that other dimensions may also be used without departing from the present disclosure, and the dimensions provided herein are for the purpose of example only.

The abundance of possible variations may be modeled for a given die design and an optimal variation selected for thermal conductivity, preservation of a ground plane, electromagnetic compatibility (EMC), electromagnetic interference (EMI) or the like. While any modeling program may be used, ANSYS is well suited for this task.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A semiconductor assembly comprising:
a die comprising a backside; and
a metallization layer patterned on the backside, wherein the metallization layer comprises at least one trench within a boundary of the metallization layer.

2. The semiconductor assembly of claim 1, wherein the metallization layer comprises gold (Au), copper (Cu), silver (Ag), nickel (Ni), platinum (Pt), titanium (Ti), chromium (Cr), Tungsten (W), or a combination of these materials.

3. The semiconductor assembly of claim 1, wherein the at least one trench comprises a plurality of trenches arranged in a rectilinear fashion.

4. The semiconductor assembly of claim 3, wherein the plurality of trenches is uniformly distributed with a constant pitch.

5. The semiconductor assembly of claim 3, wherein the plurality of trenches is non-uniformly distributed with a non-constant pitch.

6. The semiconductor assembly of claim 3, wherein the plurality of trenches comprises rounded corners for intersections of the plurality of trenches.

7. The semiconductor assembly of claim 1, wherein the at least one trench extends completely through the metallization layer.

8. The semiconductor assembly of claim 1, wherein the at least one trench only partially extends through the metallization layer leaving a fill.

9. The semiconductor assembly of claim 1, wherein the at least one trench comprises a plurality of trenches arranged with at least one arcuate segment.

10. The semiconductor assembly of claim 9, wherein the at least one arcuate segment comprises an oval.

11. The semiconductor assembly of claim 9, wherein the at least one arcuate segment comprises a plurality of concentric circles.

12. The semiconductor assembly of claim 9, wherein the plurality of trenches also includes a linear segment.

13. The semiconductor assembly of claim 1, wherein the metallization layer is at least one-tenth of a micrometer (0.1 μm) thick.

14. The semiconductor assembly of claim 1, wherein the at least one trench comprises a plurality of trenches arranged in a cross and x fashion to form triangular portions in the metallization layer.

15. The semiconductor assembly of claim 1, further comprising a lead frame attached to the metallization layer.

16. The semiconductor assembly of claim 1, wherein the metallization layer is formed on the backside.

17. The semiconductor assembly of claim 1, wherein the metallization layer is attached to the backside.
